(19) United States
(12) Patent Application Publication
(10) Pub. No.: US 2017/0358736 A1
(43) Pub. Date: Dec. 14, 2017

(54) METHOD FOR MANUFACTURING A HALL SENSOR

(71) Applicant: Robert Bosch GmbH, Stuttgart (DE)

(72) Inventors: Stefan Majoni, Weil Im Schoenbuch (DE); Christian Patak, Reutlingen (DE)

(73) Assignee: Robert Bosch GmbH, Stuttgart (DE)

(21) Appl. No.: 15/546,994

(22) PCT Filed: Jan. 13, 2016
(86) PCT No.: PCT/EP2016/050499

§ 371 Date: Jul. 27, 2017

(30) Foreign Application Priority Data
Feb. 18, 2015 (DE) 10 2015 202 871.2

(51) Int. Cl. H01L 43/04; H01L 27/22; H01L 43/06; G01R 33/00; G01R 33/07; H01L 43/14

(52) U.S. Cl. CPC H01L 43/04; G01R 33/07; H01L 43/14; H01L 43/065; G01R 33/0052; H01L 27/22

(57) ABSTRACT

A method for manufacturing a Hall sensor, an insulation layer being initially applied to a wafer including an ASIC or integrated into the wafer, a Hall layer, for example, made of InSb or another III-V semiconductor material, being situated thereon, and this Hall layer being at least sectionally recrystallized with the aid of a laser. The insulation layer may be porous or may include a cavity or reflective layer for thermal protection of the ASIC.

### FIELD

The present invention relates to a Hall sensor. The present invention furthermore relates to a method for manufacturing a Hall sensor.

### BACKGROUND INFORMATION

Hall sensors are more effective the higher the charge carrier mobility of the Hall material used is and the better a crystal quality of the Hall material is. The latter is dependent, inter alia, on a scattering of the moved charge carriers on crystal defects of the Hall material.

The silicon material has the disadvantage that it is not a good Hall material because the mobility of the charge carriers is low. However, silicon may be integrated into an ASIC process, so that low costs result for assembly and packaging technology and the Hall sensor is therefore small. Integrated silicon Hall sensors having a moderate performance are known.

In addition, separate, discrete Hall sensors made of InAs (indium arsenide), InSb (indium antimonide), and GaAs (gallium arsenide) are known, these materials having a higher Hall coefficient. For example, in the case of InSb, the mobility of the charge carriers is higher by a factor of approximately 40 than that of silicon. The square of this difference is incorporated into the electrical power consumption of the Hall sensor which is required to achieve a desired signal strength. In this way, Hall sensors are implementable, which are better by a factor of approximately 1600 than Hall sensors having silicon.

The following materials and mobilities of the charge carriers are known:

| | mobility of the charge |
|---|---|
| material | carriers [cm²/V⁻¹/s⁻¹] |
| silicon | approximately 1300 |
| InSb monocrystalline | approximately 40,000 to |
| | approximately 78,000 |
| InSb sensor | approximately 25,000 |

High temperatures are required in the manufacturing of discrete Hall sensors to achieve good crystal quality. This is implemented by high temperatures during the deposition of the Hall material or by a subsequent microzone melting method, in which the substrate having the Hall material is guided along below a hot wire, so that the melting temperature (in the case of InSb 525° C.) is locally exceeded. However, the reliability of ASICs suffers at temperatures above approximately 400° C., and does so all the more the longer the exposure lasts and the higher the temperature is.

Therefore, InSb, GaAs, InAs, and other Hall sensors are only available as separate, discrete elements, which are not integrated into the ASIC. This disadvantageously results in high costs for assembly and packaging, on the one hand, and very large modules, on the other hand, which are unfavorable to use for modern electronic devices.

### SUMMARY

It is therefore an object of the present invention to provide an improved Hall sensor.

The object may be achieved according to a first aspect of the present invention by an example Hall sensor, including:
a wafer having an ASIC;
an insulation layer provided for the wafer, the insulation layer being applied to the wafer or integrated into the wafer; and
a Hall layer situated on the insulation layer, the Hall layer having been heated with the aid of a laser in such a way that it is at least sectionally recrystallized.

The object may achieved according to a second aspect of the present invention by an example method for manufacturing a Hall sensor, including the steps:
providing a wafer having an ASIC;
forming an insulation layer, which is applied to the wafer or integrated into the wafer;
situating a Hall layer on the insulation layer; and
heating the Hall layer with the aid of a laser in such a way that the Hall layer is at least sectionally recrystallized.

It is advantageously possible using such a heat treatment of the Hall layer to provide a Hall sensor having a significantly improved mobility of the charge carriers. This is preferably achieved in that the laser heats the material of the Hall layer at least to the vicinity of the melting point and additionally beyond it.

A penetration of harmful thermal energy into the ASIC or the application-specific circuit of the wafer is prevented by the insulation layer, whereby the ASIC is advantageously not damaged by the heat of the laser. In this way, a Hall sensor may be provided, in which the Hall element is integrated into the sensor. A hybrid embodiment of the Hall sensor is advantageously not required in this way, because no additional separate chip for the Hall sensor is required. A flat construction of an electronic device (for example, a smart phone) including the Hall sensor is thus advantageously assisted.

Advantageous refinements of the Hall sensor and the method are described herein.

One advantageous refinement of the Hall sensor is distinguished in that the insulation layer is at least sectionally porous. In this way, the thermally insulating effect of the insulation layer may be increased still further, whereby improved protection of the ASIC in the wafer is possible. Furthermore, it is thus even more easily possible to melt the Hall layer with the aid of the laser. In this way, structures which are used in micromechanics may be used for the Hall sensor.

Another advantageous refinement of the Hall sensor is characterized in that the insulation layer includes at least one cavity. In this way, specific technical embodiments of the Hall sensor may be implemented, which profit from the low thermal heat capacity of the diaphragm of the insulation layer thus implemented.

One advantageous refinement of the method provides that the entire Hall layer is heat-treated with the aid of the laser. In this way, the laser may be moved in an energy-efficient way over the entire surface of the Hall layer after a single setting.

Another advantageous refinement of the method provides that the Hall layer is structured before the heat treatment with the aid of the laser in such a way that a detection structure for the Hall effect is formed. In this way, due to the pre-structuring of the Hall layer, a subsequent heat treatment by the laser advantageously only has to be limited to the detection structure.

Another advantageous refinement of the method provides that the Hall layer is only treated with the aid of the laser at points at which a detection structure is provided for the Hall effect.

The recognition of the detection structure for the Hall effect with the aid of a positioning device may thus be advantageously assisted, whereby the laser may be operated efficiently and briefly. Moreover, in this way edges of the heat-treated areas of the Hall layer do not have to be reworked.

Another advantageous refinement of the method provides that the ASIC of the wafer is protected from radiation of the laser with the aid of a protective layer, for example, an aluminum layer. In the case in which the laser inadvertently radiates past the detection structure for the Hall effect, radiant energy of the laser is rendered harmless. The sensitive application-specific integrated circuits may thus be protected from damage.

The present invention will be described in detail hereafter with further features and advantages on the basis of multiple figures. All features, regardless of their representation in the description and in the figures, form the subject matter of the present invention. The figures are intended in particular to illustrate the main principles of the present invention and are not necessarily true to scale.

### BRIEF DESCRIPTION OF THE DRAWINGS

FIG. 1 shows a cross-sectional view of an arrangement for a Hall sensor.

FIG. 2 shows a schematic view of a laser treatment of a Hall layer of the arrangement of FIG. 1.

FIGS. 3 through 6 show a sequence of a heat treatment of the Hall layer with the aid of a laser.

FIGS. 6 through 8 show a further sequence of a heat treatment of the Hall layer with the aid of a laser.

FIGS. 9 through 11 show a further sequence of a heat treatment of the Hall layer with the aid of a laser.

FIG. 12 shows a cross-sectional view of a further arrangement for a Hall sensor.

FIG. 13 shows a cross-sectional view of a further arrangement for a Hall sensor.

FIGS. 14 through 16 show cross-sectional views of multiple alternative arrangements for a Hall sensor.

FIG. 17 shows a sequence of one specific embodiment of the method according to the present invention.

### DETAILED DESCRIPTION OF EXAMPLE EMBODIMENTS

The present invention provides for initially depositing a Hall layer on an arrangement including a wafer and an insulation layer at low deposition temperature (approximately 250° C. to approximately 400° C.) and subsequently temporarily irradiating the Hall layer using a laser, so that a recrystallization process thus takes place in the Hall layer and in this way the mobility of the charge carriers of the Hall layer is increased.

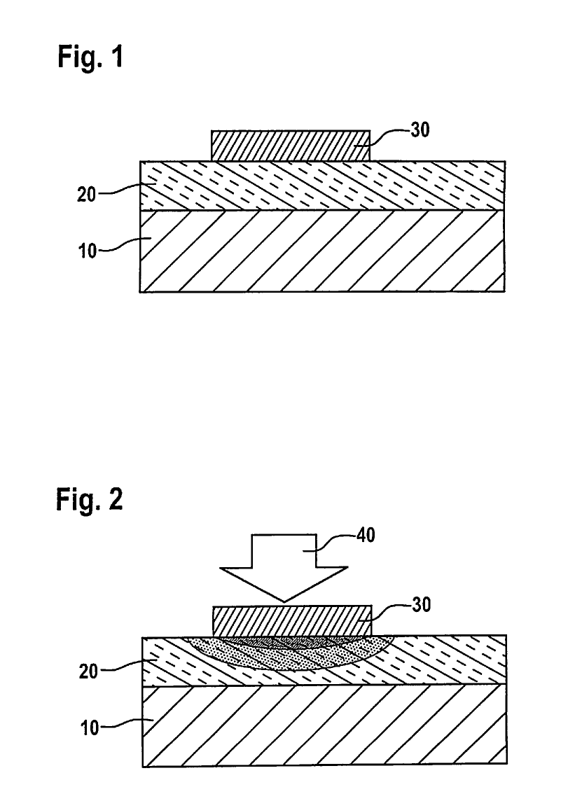

FIG. 1 shows a cross-sectional view of an arrangement for a Hall sensor including a wafer 10 having an application-specific integrated electronic circuit (ASIC, not shown) formed therein, a thermal insulation layer 20 being situated on wafer 10. Thermal insulation layer 20 may be, for example, silicon oxide, silicon nitride, oxinitride, polyimide, low-k dielectric material, porous silicone, porous oxide, one of the mentioned materials having a vacuum cavity, or the like. Alternatively or additionally, however, insulation layer 20 may already be included or integrated in wafer 10 with the ASIC. Hall layer 30 is then deposited on insulation layer 20, for example, in the form of InSb, GaAs, InAs, or another III-V semiconductor material. In the case of an integration of insulation layer 20 into wafer 10, a geometric extension of insulation layer 20 is formed as a function of a geometric extension of Hall layer 30.

FIG. 2 shows the same arrangement as FIG. 1 and is to indicate that Hall layer 30 is heat-treated temporarily and at least sectionally using an electromagnetic radiation source, preferably a laser 40. The radiation effect of laser 40 is indicated in FIG. 2 by an arrow. The thermal energy of laser 40 penetrates Hall layer 30, penetrates into insulation layer 20, and is absorbed therein. In this way, the heat of laser 40 may not have an effect into wafer 10 and in this way damage the application-specific circuit (ASIC).

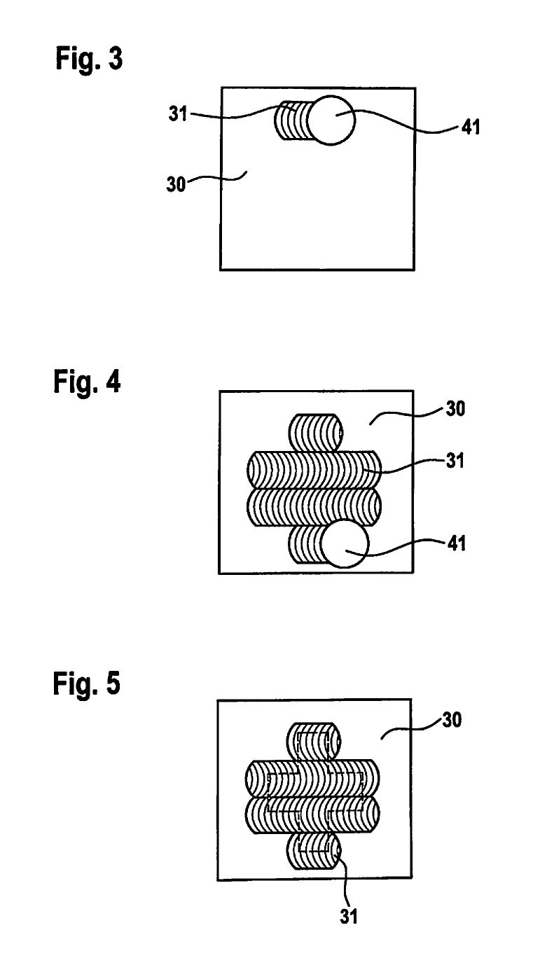

FIGS. 3 through 5 show a schematic process sequence of the method for manufacturing a Hall sensor. Laser 40 generates a laser spot 41, which moves over Hall layer 30 and thus causes local, temporary heating of Hall layer 30 and thus a recrystallization of Hall layer 30. Light bundled in a different way, for example, an IR laser, may advantageously also be used.

FIG. 3 indicates that laser spot 41 generated by laser 40 is guided sectionally over Hall layer 30. As a result, the material of Hall layer 30 is thus initially liquefied and then a recrystallization area 31 of Hall layer 30 is created, in which the above-mentioned increased charge carrier or electron mobility is present. As is apparent in FIGS. 4 and 5, laser spot 41 is moved locally defined in a linear fashion over Hall layer 30, so that as a result, as may be seen in FIG. 5, a cross-shaped detection structure (“Hall cross”) is created for the Hall effect, which is in the order of magnitude of approximately 10 μm to approximately 200 μm and is provided for sensing the Hall effect.

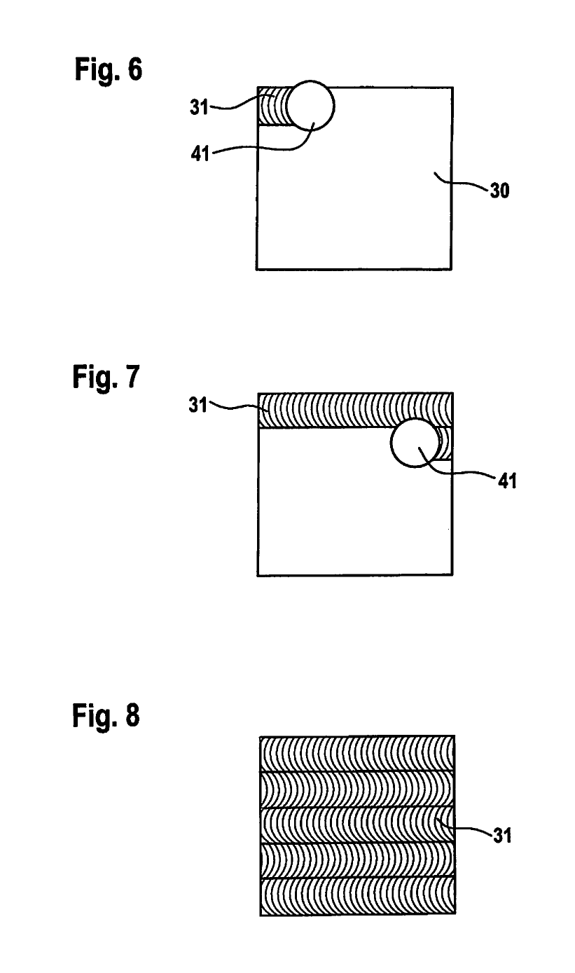

An alternative process sequence is indicated in FIGS. 6 through 8, in this case, laser spot 41 passing over the entire surface of Hall layer 30, so that recrystallization area 31 thus extends over the entire surface of Hall layer 30. In this case, turning laser 40 on and off has to be carried out more rarely in comparison to the process sequence of FIGS. 3 through 5, whereby a simpler and more energy efficient operation of laser 40 is supported.

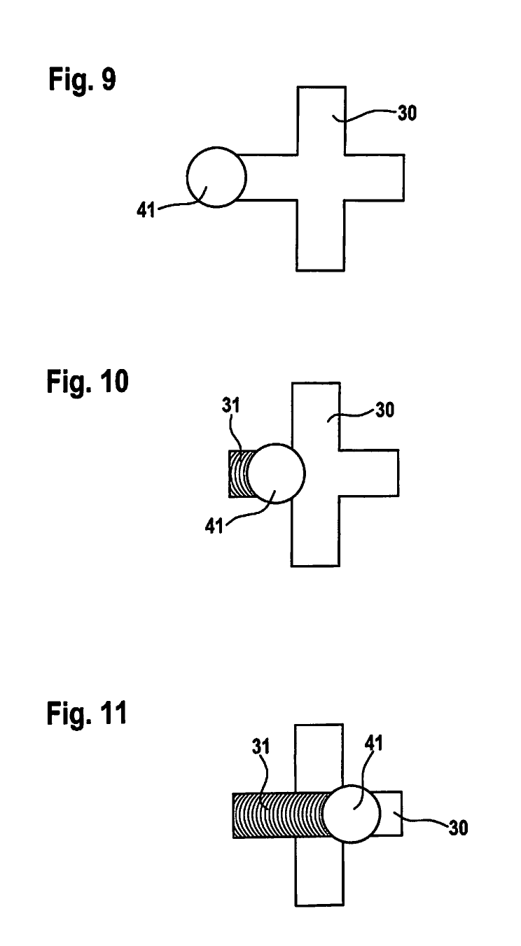

FIGS. 9 through 11 show another alternative process sequence. In this case, Hall layer 30 is initially deposited over the entire area on insulation layer 20, as in the process sequences of FIGS. 3 through 8. Hall layer 30 is then structured and the material which is not used is removed (for example, with the aid of lithography, etching, resist stripping, etc.). In this way, a detection structure for the Hall effect is produced in Hall layer 30, on which laser spot 41 is positioned, as shown in FIG. 9. By moving laser spot 41 over the detection structure, the recrystallization process of Hall layer 30 is thus limited to the detection structure. In this way, reworking of edges of the detection structure with the aid of an ion beam source is advantageously not required, whereby the edges of the detection structure are not damaged.

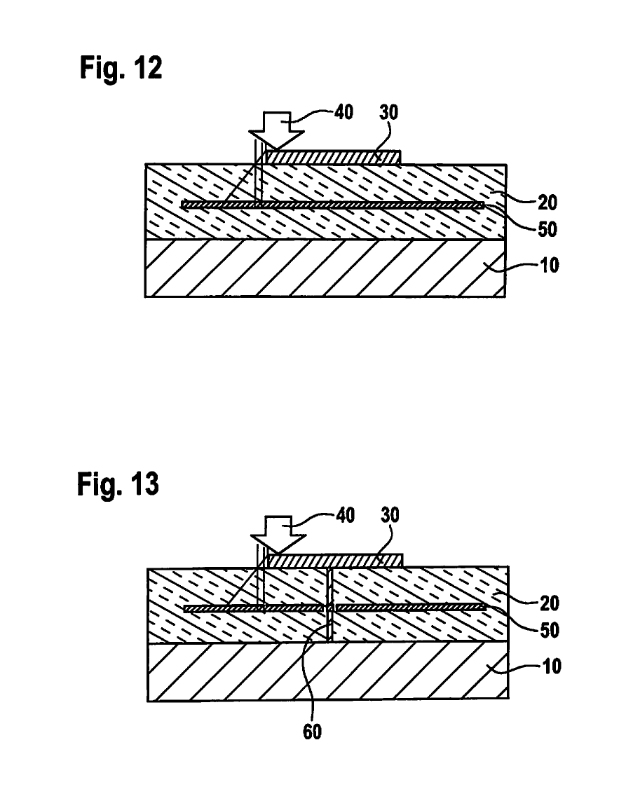

To prevent laser radiation from being able to reach wafer 10 including the ASICs or the application-specific integrated electronic circuits beyond Hall layer 30 and these circuits thus possibly being damaged, a protective layer 50 or intermediate layer is situated in insulation layer 20 below Hall layer 30. Protective layer 50 may be formed, for example, as a reflective layer made of aluminum (“light protection shield”), which reflects harmful laser radiation into insulation layer 20. FIG. 12 shows an arrangement for a Hall sensor including such a reflective layer.

FIG. 13 shows a cross-sectional view of a Hall sensor including a variant of the reflective layer, which is formed as at least partially broken through or perforated in this case. In this way, electrical vias 60 may be formed, which electrically conductively connect Hall layer 30 to the application-specific integrated circuit of wafer 10. In this way, a number of electrical connections between Hall layer 30 and the ASIC or the application-specific integrated circuit may advantageously be increased. Of course, arrangements including a further protective layer or multiple protective layers 50 are also conceivable.

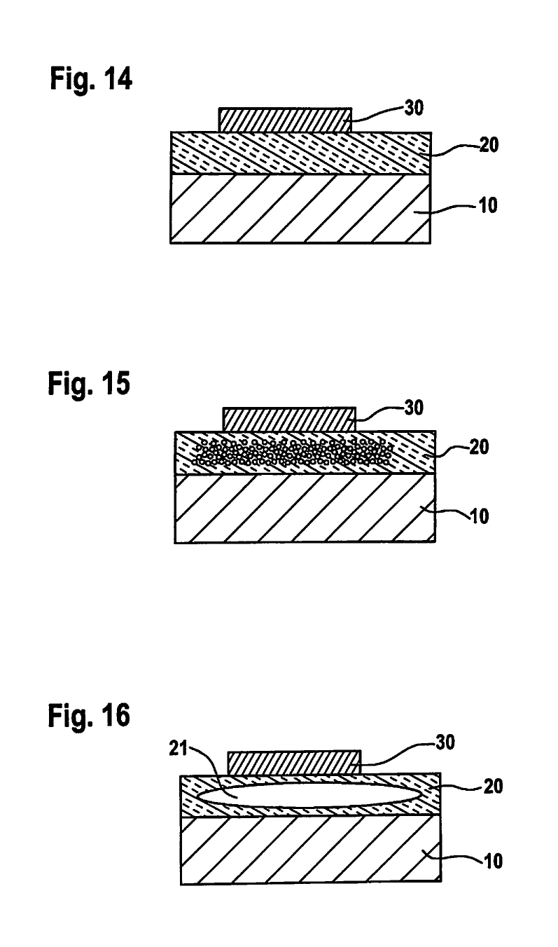

FIG. 14 once again shows a cross section through a basic shape of the arrangement for a Hall sensor. FIG. 15 shows a variant of insulation layer 20, which is formed as at least sectionally porous in this case. Structuring of insulation layer 20 may be manufactured with the aid of micromechanical methods known per se (MEMS processes). In this way, a thermal insulation effect of insulation layer 20 may still be increased, whereby an electrical power consumption of laser 40 for the thermal treatment of Hall layer 30 may advantageously be reduced.

FIG. 16 shows another variant of insulation layer 20, which in this case includes at least one cavity 21, which is preferably filled with vacuum. In this way, a diaphragm-type structure of insulation layer 20 is provided on the upper side of insulation layer 20, adjoining Hall layer 30, which may be useful for specific Hall sensors due to its low thermal heat capacity.

As a result, micromechanical structures may thus advantageously be coated using Hall layer 30. A design diversity for the Hall sensor element may thus advantageously be increased. Arbitrary combinations of insulation layer 20 shown in FIGS. 14 through 16 are also possible.

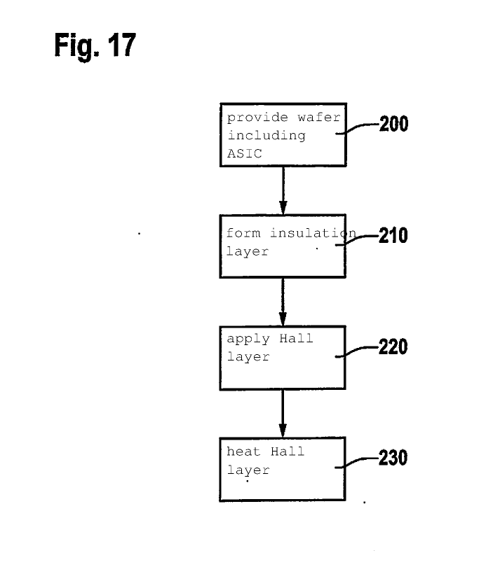

FIG. 17 shows a schematic sequence of one specific embodiment of the method according to the present invention.

In a step 200, a wafer 10 including an ASIC is provided.

In a step 210, an insulation layer 20 is formed, which is applied to wafer 10 or is integrated into wafer 10.

In a step 220, a Hall layer 30 is applied to insulation layer 20.

In a step 230, finally heating of Hall layer 30 is carried out with the aid of a laser 40 in such a way that Hall layer 30 at least sectionally recrystallizes.

In summary, a method for manufacturing a Hall sensor and a Hall sensor thus manufactured are provided by the present invention, a Hall layer initially being deposited at low temperature on an insulation layer and then being post-treated using a laser for the purpose of increasing the charge carrier mobility. This is achieved by a recrystallization process inside the Hall layer, which is generated by the temporary heating of the laser, heating of the Hall layer taking place at least to the melting point of the Hall layer and preferably beyond it.

The arrangement of the Hall layer on a defined surface of the insulation layer supports that the temperature-sensitive application-specific electronic circuits or ASICs (for example, evaluation circuits for the Hall sensor) remain largely unimpaired. Furthermore, a simpler and flatter construction of the entire arrangement is thus supported, because the Hall element may be integrated completely into the sensor.

The present invention advantageously enables, for example, electrical compasses based on III-V semiconductor Hall sensors to be manufactured, which may be integrated into smaller packing units.

Those skilled in the art will also implement specific embodiments which are not described above, without deviating from the core of the present invention.

1-10. (canceled)

11. A Hall sensor, comprising:
a wafer including an ASIC;
an insulation layer provided for the wafer, the insulation layer being one of (i) applied to the wafer, or (ii) integrated into the wafer; and
a Hall layer made of a III/V semiconductor material situated on the insulation layer, the Hall layer having been heated with the aid of a laser in such a way that it is at least sectionally recrystallized, whereby a mobility of charge carriers of the Hall layer was increased.

12. The Hall sensor as recited in claim 11, wherein the insulation layer is at least sectionally porous.

13. The Hall sensor as recited in claim 11, wherein the insulation layer includes at least one cavity.

14. A method for manufacturing a Hall sensor, comprising:
providing a wafer including an ASIC;
forming an insulation layer, the insulation layer being one of: (i) applied to the wafer, or (ii) integrated into the wafer;
situating a Hall layer made of a III/V semiconductor material on the insulation layer; and
heating the Hall layer with the aid of a laser in such a way that the Hall layer at least sectionally recrystallizes, whereby a mobility of charge carriers of the Hall layer was increased.

15. The method as recited in claim 14, wherein the insulation layer is formed as at least sectionally porous, the Hall layer being applied to the insulation layer.

16. The method as recited in claim 14, wherein the insulation layer is formed having at least one cavity, the Hall layer being applied to the insulation layer.

17. The method as recited in claim 14, wherein the entire Hall layer is heat treated with the aid of the laser.

18. The method as recited in claim 14, wherein the Hall layer is structured before the heat treatment with the aid of the laser in such a way that a detection structure for the Hall effect is formed.

19. The method as recited in claim 18, wherein only the detection structure for the Hall effect is heat treated with the aid of the laser.

20. The method as recited in claim 18, wherein the ASIC of the wafer is protected from radiation of the laser with the aid of a protective layer.

21. The method as recited in claim 20, wherein the protective layer is an aluminum layer.
